(19) United States
(12) Patent Application Publication
(10) Pub. No.: US 2006/0035411 A1
(43) Pub. Date: Feb. 16, 2006

(54) Laser processing method

(75) Inventors: Ryugo Oba, Tokyo (JP); Kenji Furuta, Tokyo (JP); Hitoshi Hoshino, Tokyo (JP); Nobuyasu Kitahara, Tokyo (JP); Noboru Takeda, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/200,142

(22) Filed: Aug. 10, 2005

(30) Foreign Application Priority Data
Aug. 11, 2004 (JP) 2004-234178

(51) Int. Cl. H01L 21/50

(52) U.S. Cl. 438/113

(57) ABSTRACT

A laser processing method for forming a laser groove along dividing lines by applying a pulse laser beam along the dividing lines formed on a workpiece, the method comprising the steps of forming the focusing spot of the pulse laser beam in a shape of oval, positioning the long axis of the oval focusing spot along each of the dividing lines, and moving the focusing spot and the workpiece along the dividing line relative to each other.

### FIELD OF THE INVENTION

The present invention relates to a method of carrying out laser processing along dividing lines called “streets formed on a workpiece such as a semiconductor wafer or the like.

### DESCRIPTION OF THE PRIOR ART

In the production process of a semiconductor device, a plurality of areas are sectioned by dividing lines called “streets” arranged in a lattice pattern on the front surface of a substantially disk-like semiconductor wafer, and a circuit (function element) such as IC or LSI is formed in each of the sectioned areas. Individual semiconductor chips are manufactured by cutting this semiconductor wafer along the dividing lines to divide it into areas having the circuit formed thereon. An optical device wafer comprising light-receiving elements (function elements) such as photodiodes or light emitting elements (function elements) such as laser diodes laminated on the front surface of a sapphire substrate is also cut along dividing lines to be divided into individual optical devices such as photodiodes or laser diodes, and these optical devices are widely used in electric equipment.

Cutting along the dividing lines of the above semiconductor wafer or optical device wafer is generally carried out by using a cutting machine called “dicer”. This cutting machine comprises a chuck table for holding a workpiece such as a semiconductor wafer or an optical device wafer, a cutting means for cutting the workpiece held on the chuck table, and a cutting-feed means for moving the chuck table and the cutting means relative to each other. The cutting means comprises a spindle unit that is equipped with a rotary spindle, a cutting blade mounted on the spindle and a drive mechanism for rotary-driving the rotary spindle. The cutting blade comprises a disk-like base and an annular cutting edge which is mounted on the side surface peripheral portion of the base and formed as thick as about 20 μm by fixing diamond abrasive grains having a diameter of about 3 μm to the base by electroforming.

Since the cutting blade has a thickness of about 20 μm, however, the dividing lines for sectioning chips must have a width of about 50 μm and hence, the area ratio of the dividing lines to the wafer is large, thereby reducing productivity. Further, since a sapphire substrate, silicon carbide substrate and the like have high Mohs hardness, cutting with the above cutting blade is not always easy. Meanwhile, as a means of dividing a plate-like workpiece such as a semiconductor wafer, a method in which a pulse laser beam is applied along dividing lines formed on the workpiece to form a laser groove and the workpiece is divided along the laser groove is proposed by JP-A 10-305420.

As the laser groove formed by laser processing is shallow, the laser beam application step must be carried out several times along the same dividing line in order to form a laser groove having a predetermined depth in the workpiece. Therefore, to improve the processing efficiency of laser processing, how the processing depth of each time of the laser beam application step can be made large becomes important. Further, since the focusing spot of a laser beam applied for laser processing has a round shape in the prior art, when the pulse laser beam is applied along the dividing lines of the workpiece, a molten debris is produced and fills the formed laser groove. Consequently, problems arise in that a laser beam applied next is cut off or the focusing spot of the laser beam cannot be set to the bottom of the laser groove, thereby making it impossible to form laser grooves having a predetermined depth efficiently.

### SUMMARY OF THE INVENTION

It is an object of the present invention to provide a laser processing method capable of increasing a processing depth of a laser groove formed by one time of laser processing and carrying out processing without accumulating debris produced by the application of a laser beam in a groove having been formed by laser processing.

To attain the above principal technical object, there is provided a laser processing method for forming a laser groove along dividing lines by applying a pulse laser beam along the dividing lines formed on a workpiece, the method comprising the steps of:

forming a focusing spot of the pulse laser beam in a shape of an oval;

positioning the long axis of the oval focusing spot along each of the dividing lines; and

processing-feeding the focusing spot and the workpiece along the dividing line relative to each other.

Preferably, the ratio of the length d1 (mm) of the long axis to the length d2 (mm) of the short axis of the oval focusing spot is set to 4:1 to 12:1. Preferably, when the length of the long axis of the oval focusing spot is represented by d1 (mm), the frequency of the pulse laser beam is represented by Z (Hz) and the processing-feed rate is represented by V (mm/sec), the relationship d1>V/Z is set to be satisfied. Preferably, the energy distribution on the short axis side of the oval focusing spot is changed from a Gaussian distribution to a top hat distribution.

According to the present invention, since the focusing spot is formed into a shape of oval, the converging rate on the long axis side is smaller than the converging rate on the short axis side, and the change rate of the area of the spot is smaller than the change rate of the area of the round spot of the laser beam. Therefore, when a laser beam capable of obtaining predetermined output per unit area at the focusing point is applied, a laser beam having an oval spot has higher output per unit area than a laser beam having a round spot at a position of predetermined distance a part from the focusing point, and hence, a laser beam L having an oval spot has a larger processable depth (focusing depth) than a laser beam having a round spot, thereby making it possible to increase the processing depth of a laser groove formed by one time of laser processing.

As for a laser beam having an oval spot, as its converging rate on the long axis side is smaller than the converging rate on the short axis side, a change in the energy distribution in the processing direction becomes gentle. As a result, debris produced by the application of a laser beam is scattered and discharged along the tangent direction of this energy distribution which changes gently, and does not accumulate in the formed laser groove.

### BRIEF DESCRIPTION OF THE DRAWINGS

FIG. 1 is a perspective view showing a state where a semiconductor wafer to be processed by the laser processing method of the present invention is mounted on a frame through a protective tape;

FIG. 2 is a perspective view of the principal section of a laser beam processing machine for carrying out the laser processing method of the present invention;

FIG. 3 is a block diagram schematically showing the constitution of a laser beam application means provided in the laser beam processing machine shown in FIG. 2;

FIG. 4 is a block diagram of a pulse laser oscillation means and a transmission optical system constituting the laser beam application means shown in FIG. 3;

FIGS. 5(a) and 5(b) are explanatory diagrams of a laser groove forming step in the laser processing method of the present invention;

FIG. 6 is an enlarged sectional view of the principal section of a semiconductor wafer having a laser groove formed by the laser processing method of the present invention;

FIGS. 7(a) and 7(b) are explanatory diagrams showing the focusing spots of a laser beam having a round spot and a laser beam having an oval spot, respectively;

FIG. 8 is an explanatory diagram showing a state where the adjacent oval spots of a pulse laser beam are overlapped one another in the laser processing method of the present invention;

FIG. 9 is an enlarged sectional view of the principal section of a semiconductor wafer having a laser groove formed by carrying out the laser groove forming step several times according to the laser processing method of the present invention;

FIG. 10 is a graph showing the relationship between the ratio of the long axis to the short axis of a pulse laser beam having an oval spot and the depth of a laser groove;

FIGS. 11(a) and 11(b) are explanatory diagrams showing a processing state by a laser beam having a round spot and a processing state by a laser beam having an oval spot, respectively;

FIG. 12 is a block diagram showing a pulse laser oscillation means and a transmission optical system constituting the laser beam application means shown in FIG. 3 according to another embodiment of the present invention; and

FIG. 13 is an explanatory diagram showing the energy distribution of a laser beam applied by the laser beam application means shown in FIG. 12.

### DETAILED DESCRIPTION OF THE PREFERRED EMBODIMENTS

The laser processing method of the present invention will be described in more detail hereinunder with reference to the accompanying drawings.

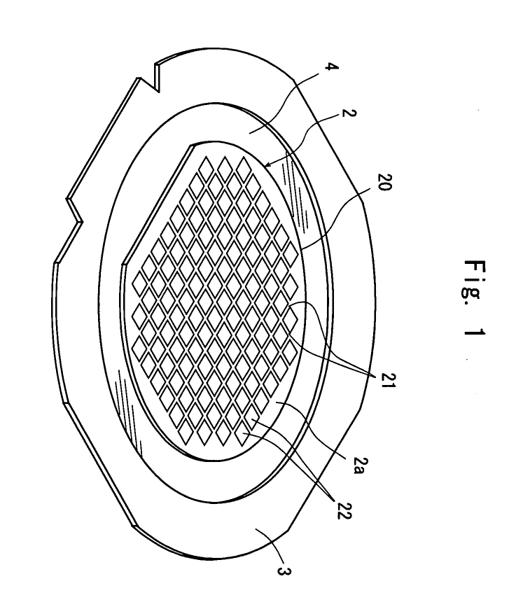

FIG. 1 is a perspective view of a semiconductor wafer as a workpiece to be processed by the laser processing method of the present invention. In the semiconductor wafer 2 shown in FIG. 1, a plurality of areas are sectioned by a plurality of dividing lines 21 arranged in a lattice pattern on the front surface 20a of a semiconductor substrate 20 such as a GaAs substrate and a device 22 such as IC or LSI is formed in each of the sectioned areas. A back surface of the thus constituted semiconductor wafer 2 is put on a protective tape 4 mounted on an annular frame 3 in such a manner that the front surface 2a, that is, the surface, on which the dividing line 21 and device 22 are formed, faces up.

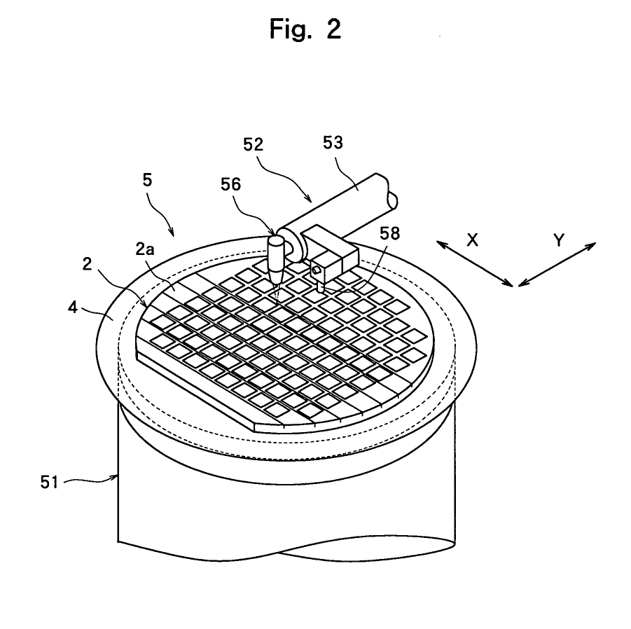

FIGS. 2 to 4 show a laser beam processing machine for carrying out the laser processing method of the present invention. The laser processing method of the present invention is carried out by using the laser beam processing machine shown in FIGS. 2 to 4. The laser beam processing machine 5 shown in FIGS. 2 to 4 comprises a chuck table 51 for holding a workpiece, a laser beam application means 52 for applying a laser beam to the workpiece held on the chuck table 51, and an image pick-up means 58 for picking up an image of the workpiece held on the chuck table 51. The chuck table 51 is so constituted as to suction-hold the workpiece and is designed to be moved in a processing-feed direction indicated by an arrow X and an indexing-feed direction indicated by an arrow Y in FIG. 2 by a moving mechanism that is not shown.

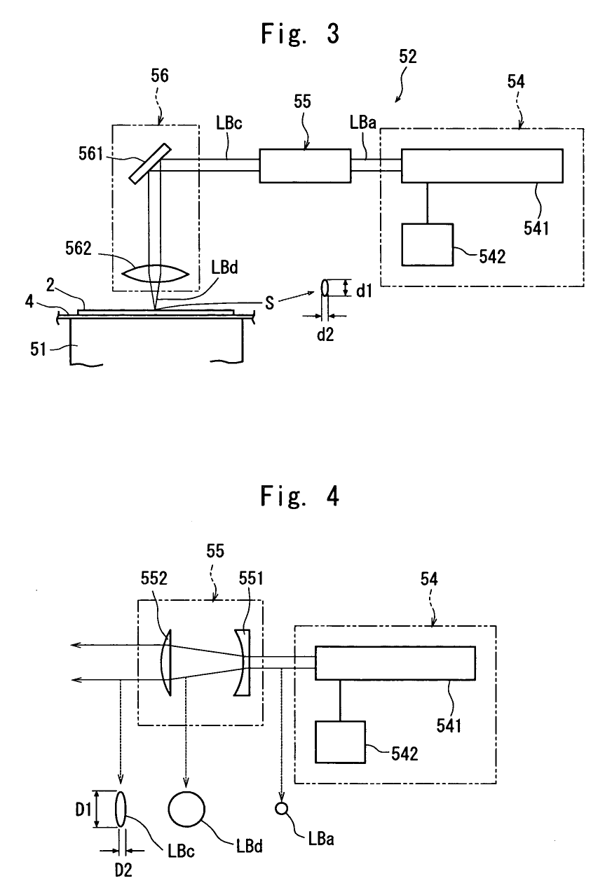

The above laser beam application means 52 has a cylindrical casing 53 arranged substantially horizontally. In the casing 53, as shown in FIG. 3, there are installed a pulse laser beam oscillation means 54 and a transmission optical system 55. The pulse laser beam oscillation means 54 comprises a pulse laser beam oscillator 541 composed of a YAG laser oscillator or YVO4 laser oscillator and a repetition frequency setting means 542 connected to the pulse laser beam oscillator 541.

The transmission optical system 55 comprises a beam expanding lens 551 and an oval shaping lens 552, as shown in FIG. 4. A laser beam LBa having a round spot (shape of cross section) applied from the above pulse laser beam oscillation means 54 is expanded into a laser beam LBb having a round spot (shape of cross section) by the beam expanding lens 551 and further formed into a laser beam LBc having an oval spot (shape of cross section) (its long axis is D1 and its short axis is D2) by the oval shaping lens 552.

Returning to FIG. 3, a condenser 56 is mounted on the end of the above casing 53. The condenser 56 has a direction-changing-mirror 561 and an objective condenser lens 562, as shown in FIG. 3. Therefore, the laser beam LBc (its focusing spot is oval with a long axis D1 and a short axis D2) applied from the above pulse laser beam oscillation means 54 through the transmission optical system 55 is deflected by the direction-changing-mirror 561 at right angles, converged by the above objective condenser lens 562 and then applied as a pulse laser beam LBd to the workpiece held on the above chuck table 51 at a focusing spot S. This focusing spot S has an oval shape of cross section with a long axis d1 and a short axis d2.

Returning to FIG. 2, the image pick-up means 58 mounted on the end of the casing 53 constituting the above laser beam application means 52 is constituted by an ordinary image pick-up device (CCD) for picking up an image with visible radiation in the illustrated embodiment, and supplies the obtained image signal to a control means that is not shown.

The laser processing method which is carried out along the dividing lines 21 of the above semiconductor wafer 2 by using the above-described laser beam processing machine 5 will be described with reference to FIG. 2 and FIGS. 5 to 9.

To carry out laser processing along the dividing lines 21 of the above semiconductor wafer 2, the semiconductor wafer 2 is first placed on the chuck table 51 of the laser beam processing machine 5 shown in FIG. 2 in such a manner that the front surface 2a faces up, and suction-held on the chuck table 51. Although the annular frame 3 mounted on the protective tape 4 is not shown in FIG. 2, it is held on a suitable frame holding means arranged on the chuck table 51.

The chuck table 51 suction-holding the semiconductor wafer 2 as described above is positioned right below the image pick-up means 58 by a moving mechanism that is not shown. After the chuck table 51 is positioned right below the image pick-up means 58, an alignment work for detecting the area to be processed of the semiconductor wafer 2 is carried out by using the image pick-up means 58 and the control means that is not shown. That is, the image pick-up means 58 and the control means (not shown) carry out image processing such as pattern matching, etc. to align a dividing line 21 formed in a predetermined direction of the semiconductor wafer 2 with the condenser 56 of the laser beam application means 52 for applying a laser beam along the dividing line 21, thereby performing the alignment of a laser beam application position. The alignment of the laser beam application position is also similarly carried out on dividing lines 21 formed on the semiconductor wafer 2 in a direction perpendicular to the predetermined direction.

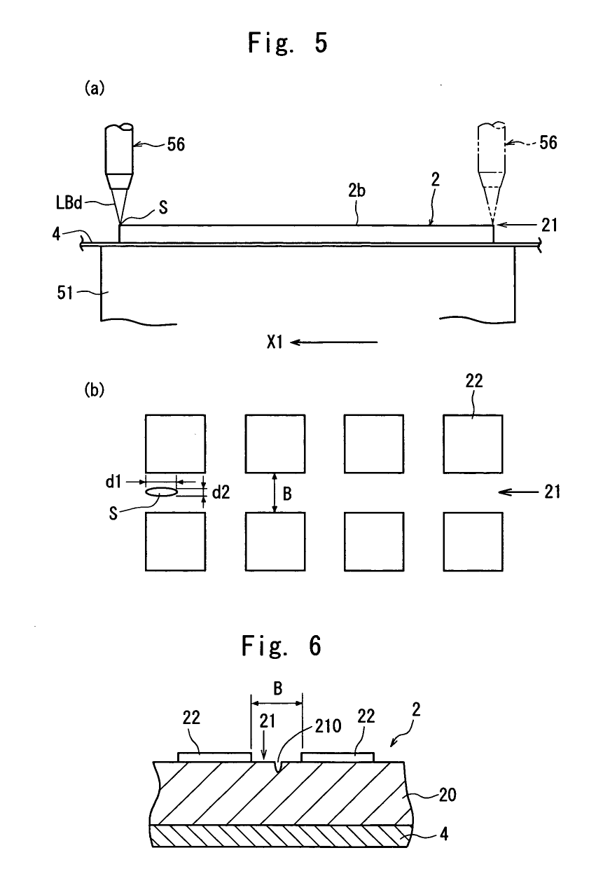

After the dividing line 21 formed on the semiconductor wafer 2 held on the chuck table 51 is detected and the alignment of the laser beam application position is carried out as described above, the chuck table 51 is moved to a laser beam application area where the condenser 56 of the laser beam application means 52 for applying a laser beam is located to bring one end (left end in FIG. 5(a)) of the predetermined dividing line 21 to a position right below the condenser 56 of the laser beam application means 52, as shown in FIG. 5(a). At this point, as shown in FIG. 5(b), the long axis d1 at the oval focusing spot S of the laser beam LBd applied from the condenser 56 is positioned along the dividing line 21. The width of the short axis d2 at the focusing spot S is set smaller than the width B of the dividing line 21.

The chuck table 51, that is, the semiconductor wafer 2 is then moved in the direction indicated by the arrow X1 in FIG. 5(a) at a predetermined processing-feed rate while the pulse laser beam LBd is applied from the condenser 56. When the other end (right end in FIG. 5(a)) of the dividing line 21 reaches the application position of the condenser 56 of the laser beam application means 52, the application of the pulse laser beam is suspended and the movement of the chuck table 51, that is, the semiconductor wafer 2 is stopped. As a result, a laser groove 210 is formed along the dividing line 21 in the semiconductor wafer 2 as shown in FIG. 6 (a laser groove forming step).

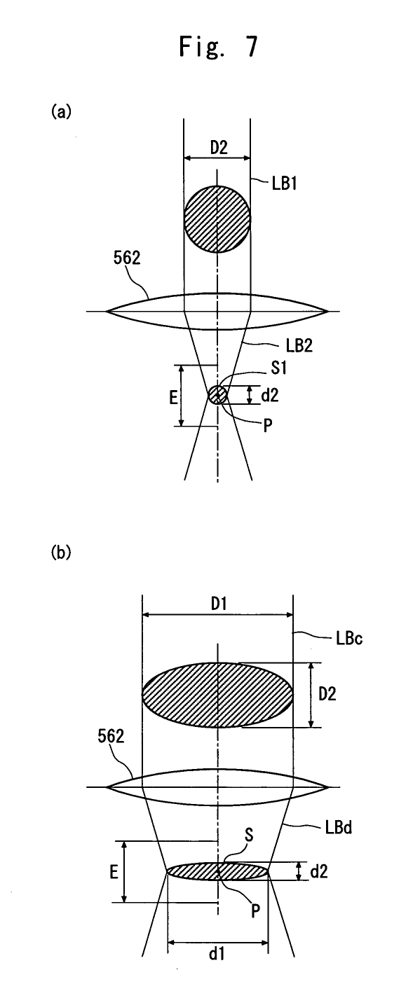

Since the focusing spot S of the laser beam applied to the semiconductor wafer 2 is formed in a shape of oval in the above laser groove forming step, the converging rate on the long axis side of the oval spot S at the focusing point converged by the objective condenser lens 562 is smaller than that of a laser beam having a round spot. This will be described with reference to FIGS. 7(a) and 7(b). FIG. 7(a) shows that a laser beam LB1 having a round spot is applied to the objective condenser lens 562. As shown in FIG. 7(a), the laser beam LB1 (diameter of D2) having a round spot applied to the objective condenser lens 562 is converged into a laser beam LB2 (diameter of d2) having a round spot S1 at the focusing point P. Meanwhile, FIG. 7(b) shows that the laser beam LBc having an oval spot is applied to the objective condenser lens 562. As shown in FIG. 7(b), the laser beam LBc (its long axis is D1 and its short axis is D2) having an oval spot applied to the objective condenser lens 562 is converged into a laser beam LBd (its long axis is d1 and its short axis is d2) having an oval spot S at the focusing point P. In the case of the laser beam LBc having an oval spot, as D2 on the short axis side is converged into d2 at the focusing point P, the converging rate is substantially the same as that of the laser beam LB1 having a round spot. However, as D1 on the long axis side is converged into d1, the converging rate is smaller than that of the short axis. Consequently, the change rate of the spot area of the laser beam LBd having an oval spot is smaller than that of the laser beam LB2 having a round spot. Therefore, when a laser beam from which predetermined output per unit area is obtained at the focusing point P is applied, at a position predetermined distance apart from the focusing point P, the output per unit area of the laser beam LBd having an oval spot is larger than that of the laser beam LB2 having a round spot. That is, the processible depth (focusing depth) E of the laser beam LBd having an oval spot is larger than that of the laser beam LB2 having a round spot.

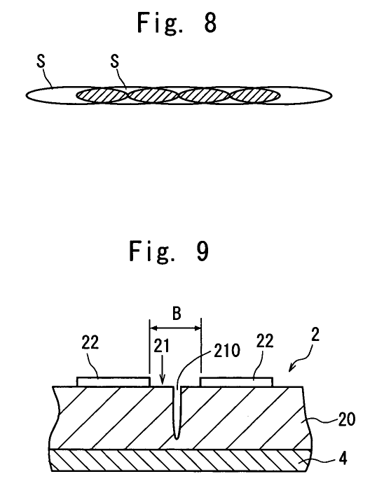

The laser beam LB is applied from the condenser 56 to the semiconductor wafer 2 at an oval spot S as described above. When the repetition frequency of the pulse laser beam is represented by Z (Hz), the processing-feed rate by V (mm/sec) and the length (length in the processing-feed direction) of the long axis of the spot S of the pulse laser beam by d1, by setting the processing conditions so as to satisfy the expression d1>(V/Z), the adjacent spots S of the pulse laser beam partially overlap with one another in the feed direction X, that is, along the dividing line 21, as shown in FIG. 8. In the example shown in FIG. 8, the overlap rate in the processing-feed direction X of the spots S of the pulse laser beam is 50%. This overlap rate can be suitably set by changing the processing-feed rate V (mm/sec) or the length in the processing-feed direction of the spot S of the pulse laser beam.

The above laser groove forming step is carried out under the following conditions, for example.

Light source: YVO4 laser or YAG laser

Wavelength: 355 nm

Average output: 2 W

Repetition frequency: 30 kHz

Pulse width: 100 ns

Size of spot S: 20 μm in height×40 μm in length, 20 μm in height×20 μm in length

Processing-feed rate: 400 mm/sec

Number of repeated processing: 8

By carrying out the above laser groove forming step eight times, for example, a laser groove 210 having a width not larger than the width B of the dividing line 21 is formed on the GaAs substrate 20 along the dividing line 21 of the semiconductor wafer 2, as shown in FIG. 8.

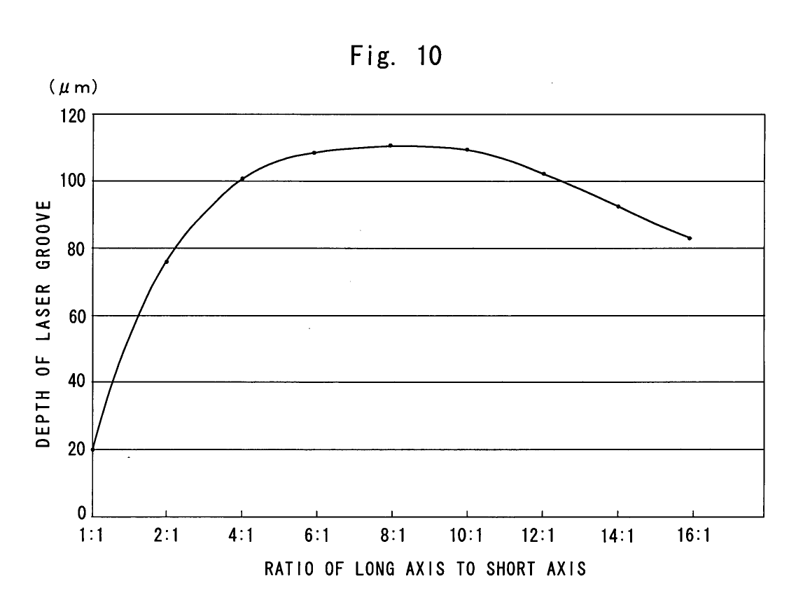

The results of experiments on the processing depth of the laser groove 210 formed in the above-described laser groove forming step will be described hereinunder. FIG. 10 shows the depth of a laser groove obtained when the laser groove forming step was carried out on a GaAs wafer having a diameter of 100 mm and a thickness of 0.2 mm along the same dividing line eight times under the above processing conditions. In the experiments, the application of a laser beam was carried out without changing the height position (position in the Z direction) of the condenser 56. In FIG. 10, the horizontal axis shows the ratio of the long axis d1 to the short axis d2 of a laser beam having an oval spot and the vertical axis shows the depth of a laser groove. When the ratio of the long axis d1 to the short axis d2 plotted on the horizontal axis of FIG. 10 is 1:1, the laser beam has a round spot. As understood from FIG. 10, when processing is carried out with a laser beam having an oval spot, the obtained groove becomes deeper than when processing is carried out with a laser beam having a round spot. Particularly when the ratio of the long axis d1 to the short axis d2 of the oval spot is in the range of 4:1 to 12:1, the depth becomes 5 times or more that of the laser beam having a round spot, thereby greatly improving the processing efficiency. Therefore, it is desired to set the ratio of the long axis d1 to the short axis d2 of the spot of the laser beam having an oval spot to 4:1 to 12:1.

The discharge direction of debris produced by the application of the laser beam to the wafer is to be studied next.

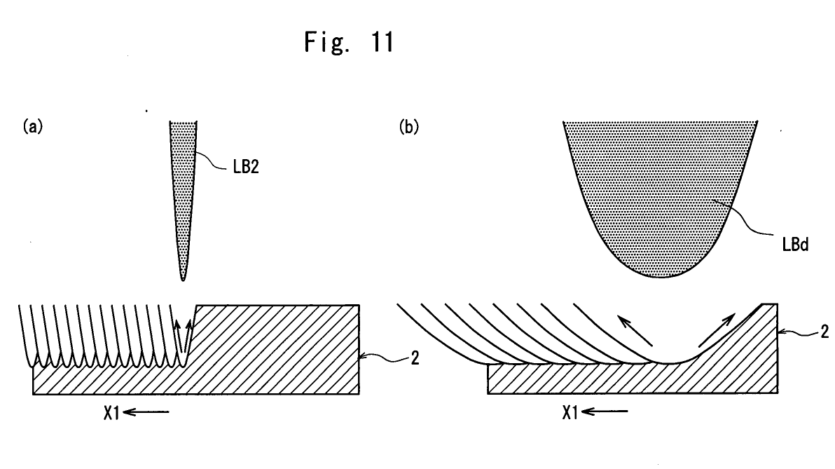

FIG. 11(a) shows a processing state seen from a direction perpendicular to the processing direction when the laser beam LB2 having a round spot is applied to the semiconductor wafer 2 as the workpiece. Since the laser beam LB2 having a round spot has substantially the same converging rate in the processing direction X1 as that in all the directions as shown in FIG. 11(a), it is applied to the semiconductor wafer 2 with an energy distribution having an acute angle. Although debris produced by the application of the laser beam are scattered in the tangent direction of the energy distribution (Gaussian distribution), as the energy distribution (Gaussian distribution) in the processing direction X of the laser beam L2 having a round spot also has an acute angle, the debris are scattered upward and accumulated in the previously formed laser groove. The debris thus accumulated in the laser groove become an obstacle to the application of the next laser beam along the laser groove.

FIG. 11(b) shows a processing state seen from a direction perpendicular to the processing direction when the laser beam LBd having an oval spot is applied to the semiconductor wafer 2 as the workpiece. Since as shown in FIG. 11(b), the laser beam LBd having an oval spot has a small converging rate in the processing direction X1 (long axis direction of the spot) as described above, a change in the energy distribution (Gaussian distribution) in the processing direction X1 becomes gentle. As a result, debris produced by the application of the laser beam are scattered and discharged along the tangent direction of the energy distribution (Gaussian distribution) which changes gently, whereby they are not accumulated in the previously formed laser groove.

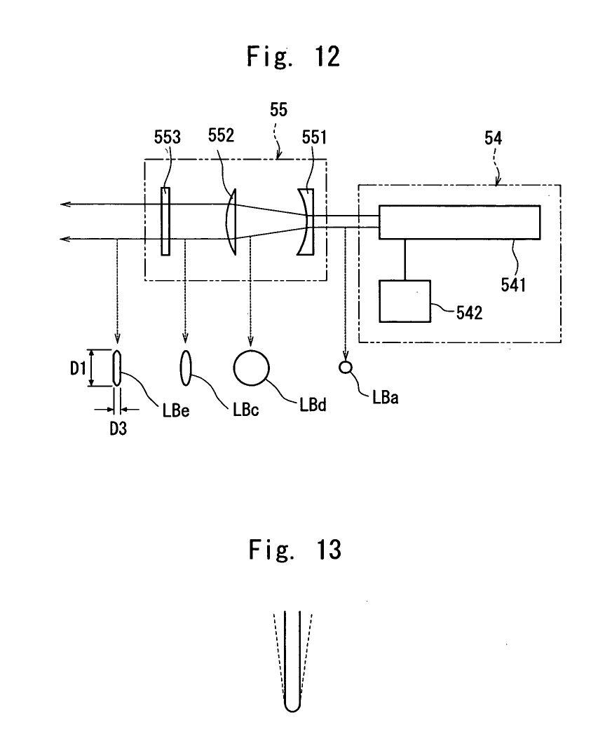

A description will be subsequently given of another embodiment of the laser processing method of the present invention with reference to FIG. 12.

In the embodiment shown in FIG. 12, the laser beam applied through the transmission optical system 55 shown in FIG. 4 in the above embodiment is changed in the shape of the spot. That is, a laser beam LBe which has been masked on the short axis D3 side is formed by passing the laser beam LBc having an oval spot (shape of cross section) (its long axis is D1 and its short axis is D2) formed by the oval shaping lens 552 in the transmission optical system, through a rectangular hat top mask 553. This laser beam LBe has a long axis length of D1 and a short axis width of D3. Since the embodiment shown in FIG. 12 is substantially the same as the embodiment shown in FIG. 4 except that the rectangular hat top mask 553 is provided, the same members are given the same reference symbols and their detailed descriptions are omitted.

Since the laser beam LBe (its long axis is D1 and its short axis is D3) which has been masked on the short axis D3 side is formed by passing the laser beam LBc having an oval spot (shape of cross section) (its long axis is D1 and its short axis is D2) formed by the oval shaping lens 552 through the rectangular hat top mask 553 in the embodiment shown in FIG. 12, the energy distribution on the short axis D3 side becomes a so-called “top hat distribution” shown by a solid line from a Gaussian distribution shown by a broken line, as shown in FIG. 13. Therefore, the energy distribution on the both sides in the width direction of the laser groove becomes large, whereby the both sides of the laser groove can be processed sharply and hence, the occurrence of peeling-off on the both sides of the laser groove can be prevented.

While the present invention has been described based on the illustrated embodiments, it should be noted that the present invention is in no way limited thereto but can be changed or modified in other various ways without departing from the scope of the present invention. In the illustrated embodiments, the present invention is applied to a wafer comprising a GaAs substrate. It is needless to say that the present invention can be applied to a wafer comprising another substrate such as a sapphire substrate. Further, although the laser groove has been formed from the front surface of the wafer in the illustrated embodiments, the laser groove may be formed from the back surface of the wafer by applying a laser beam from the back surface of the wafer along the dividing lines. In this case, the dividing lines formed on the front surface of the wafer are detected from the back surface by an infrared camera at the time of the above alignment work. Further, although the oval shaping lens 552 and the rectangular hat top mask 553 are provided in the transmission optical system 55 in the illustrated embodiment, they may be provided in the condenser 56. Further, although the laser beam is applied at a constant output in the above embodiments, the output may be changed according to the depth of a laser groove. Further, an inert gas such as nitrogen gas or argon gas may be supplied to the processing area during laser processing.

What is claimed is:

1. A laser processing method for forming a laser groove along dividing lines by applying a pulse laser beam along the dividing lines formed on a workpiece, the method comprising the steps of:
forming the focusing spot of the pulse laser beam in a shape of oval;
positioning the long axis of the oval focusing spot along each of the dividing lines; and
moving the focusing spot and the workpiece along the dividing line relative to each other.

2. The laser processing method according to claim 1, wherein the ratio of the length d1 (mm) of the long axis to the length d2 (mm) of the short axis of the oval focusing spot is set to 4:1 to 12:1.

3. The laser processing method according to claim 1, wherein when the length of the long axis of the oval focusing spot is represented by d1 (mm), the frequency of the pulse laser beam is represented by Z (Hz) and the processing-feed rate is represented by V (mm/sec), the relationship d1>(V/Z) is set to be satisfied.

4. The laser processing method according to claim 1, wherein the energy distribution on the short axis side of the oval focusing spot is changed from a Gaussian distribution to a top hat distribution.
